(19) United States
(12) Patent Application Publication
(10) Pub. No.: US 2016/0349718 A1
(43) Pub. Date: Dec. 1, 2016

(54) APPARATUS FOR COATING PHOTORESIST AND THE METHOD THEREOF

(71) Applicant: SHENZHEN CHINA STAR OPTOELECTRONICS TECHNOLOGY CO. LTD., Guangdong (CN)

(72) Inventors: Song WANG, Shenzhen, Guangdong (CN); Jialong LIN, Shenzhen, Guangdong (CN)

(73) Assignee: Shenzhen China Star Optoelectronics Technology Co. Ltd., Shenzhen, Guangdong (CN)

(21) Appl. No.: 14/435,703

(22) PCT Filed: Jan. 7, 2015
(86) PCT No.: PCT/CN2015/070272

§ 371 Date: Apr. 14, 2015

(30) Foreign Application Priority Data
Dec. 29, 2014 (CN) 201410836654.8

(51) Int. Cl. G05B 15/02; G03F 7/16

(52) U.S. Cl. CPC G05B 15/02; G03F 7/16

(57) ABSTRACT

An apparatus and a method for coating photoresist are disclosed. The apparatus comprises a workbench, a nozzle, a nozzle drive, a detection device and a controller. The substrate to be coated is disposed on the workbench, the nozzle drive drives the movement of the nozzle above the substrate on the workbench, the nozzle is disposed across the substrate, the detection device is disposed across the substrate and is parallel to the nozzle, the detection device detects the variation of the altitude of the surface of the substrate and computes the variation curve of the interval between the nozzle and the substrate, the controller controls the nozzle drive according to the variation curve computed by detection device, so that the nozzle drive forces the nozzle moving and adjusts the vertical distance between the nozzle and the substrate according to the variation curve of the interval.

### CROSS REFERENCE TO RELATED APPLICATION

This application claims priority on “Apparatus for coating photoresist and the method thereof” of Patent Application No(s). 201410836654.8 filed on Dec. 29, 2014, the entire content of which is hereby incorporated by reference.

### BACKGROUND OF THE INVENTION

1. Field of the Invention

The disclosure is related to an apparatus for coating photoresist and the method thereof, and more particularly, to an apparatus for coating photoresist configured to coat photoresist materials on a substrate and the method thereof.

2. Description of Related Art

Before coating photoresist on the panel, substrates are stacked by different kinds of films with different patterns, so that the altitude of the surface varies. Currently, slit coating is more popular. In the method, the apparatus comprises a carrier of a substrate and a slit coater disposed across the substrate. When the slit coater moves toward the direction, which is perpendicular to the direction the slit coater disposed along with, the coater coats materials, such as photoresist, on the substrate according to the set of the pressure, the velocity and the gap. During the process of coating, the gap is remained as a constant, and does not verify during the coating process. Since the surface of the substrate is not flat because of the stacked patterns before coating, the thickness of the film, which is coated by slit coating, is not uniform, so that the performance of the liquid crystal displays is affected.

### SUMMARY OF THE INVENTION

The technique problem solved by the disclosure is to provide an apparatus for coating photoresist and the method thereof, so that the thickness of the coated film is uniform, and the performance of liquid crystal displays is improved.

In order to achieve the above purpose, the disclosure provides the following technical solutions.

According to an embodiment of the disclosure, the disclosure provides an apparatus for coating photoresist, configured to coat a film on a substrate, characterized by the apparatus for coating photoresist comprising a workbench, a nozzle, a nozzle drive, a detection device and a controller, wherein the substrate is disposed on the workbench, the nozzle drive is configured to drive the movement of the nozzle above the substrate on the workbench, the nozzle is disposed across the substrate, the detection device is disposed across the substrate, the detection device is parallel to the nozzle, the detection device is configured to detect the variation of the altitude of the surface of the substrate and compute the variation curve of the interval between the nozzle and the substrate, the controller controls the nozzle drive according to the variation curve of the interval between the nozzle and the substrate computed by detection device, so that the nozzle drive forces the nozzle moving and adjusts the vertical distance between the nozzle and the substrate according to the variation curve of the interval.

Wherein, the detection device is a reflective laser detector, the detection device comprises an emitter, a receiver and a computing unit, the emitter and the receiver are disposed above the workbench and are configured to emit and receive a laser beam, the laser beam passes across the substrate, and the detection device moves from one side of the workbench to the opposite side so as to accomplish scanning the substrate.

Wherein, the controller comprises a mean unit, the mean unit computes an average value of the distance of the interval between the nozzle and each of the point on the substrate according to the variation curve of the interval, the controller emits the average value to the nozzle drive, and the nozzle drive positions the nozzle, so that the vertical distance between the nozzle and the substrate is equal to the average value.

Wherein, the controller further comprises a curve amending unit and a detecting unit, the detecting unit is configured to detect the variation of the variation curve of the interval, when the variation curve having a sudden increase or decrease is detected, the curve amending unit amends the variation curve of the interval, so as to smoothen the position of the sudden increase or decrease, and the controller controls the nozzle drive according to the amended variation curve of the interval.

Wherein, the controller further comprises an alerting unit, when the difference between the maximum value or the minimum value of the variation curve of the interval and the average value is greater than a predetermined range is detected by the detecting unit, then the alerting unit is activated.

According to another embodiment of the disclosure, the disclosure provides a method for coating photoresist, comprising: detecting the variation of the altitude of the surface of a substrate by a detection device; computing the variation curve of the interval between a nozzle and the substrate by a detection device; receiving the variation curve of the interval and controlling a nozzle drive by a controller; the nozzle drive forcing the nozzle moving and adjusting the vertical distance between the nozzle and the substrate according to the variation curve of the interval.

Wherein, the detection device is a reflective laser detector, the detection device comprises an emitter, a receiver and a computing unit, the emitter and the receiver are disposed above a workbench and are configured to emit and receive a laser beam, the laser beam passes across the substrate, and the detection device moves from one side of the workbench to the opposite side so as to accomplish scanning the substrate.

Wherein, after the step of receiving the variation curve of the interval by a controller and before the step of controlling a nozzle drive by the controller, the method further comprises: a mean unit in the controller computing an average value of the distance of the interval between the nozzle and each of the point on the substrate according to the variation curve of the interval; the controller emitting the average value to the nozzle drive; the nozzle drive poisoning the nozzle, so that the vertical distance between the nozzle and the substrate being equal to the average value.

Wherein, after the step of computing an average value of the distance of the interval between the nozzle and each of the point on the substrate by the controller, the method further comprises: detecting the variation of the variation curve of the interval by a detecting unit of the controller, when the variation curve having a sudden increase or decrease being detected, a curve amending unit of the controller amending the variation curve of the interval, so as to smoothen the position of the sudden increase or decrease, and the controller controlling the nozzle drive according to the amended variation curve of the interval.

Wherein, when the difference between the maximum value or the minimum value of the variation curve of the interval and the average value being greater than a predetermined range is detected by the detecting unit, then an alerting unit is activated.

According to the embodiment of the disclosure, the detection device detects the variation of the altitude of the surface of the substrate and computes the variation curve of the interval between the nozzle and the substrate, the controller controls the nozzle drive according to the variation curve of the interval computed by detection device, so that the nozzle drive forces the nozzle moving and adjusts the vertical distance between the nozzle and the substrate. Thus, during the process of coating, the vertical distance between the nozzle and the substrate can be remained consistently, so that the thickness of the coated film is uniform, and the performance of liquid crystal displays is improved.

### BRIEF DESCRIPTION OF THE DRAWINGS

The above and other exemplary aspects, features and advantages of certain exemplary embodiments of the present disclosure will be more apparent from the following description taken in conjunction with the accompanying drawings, in which:

FIG. 1 is a schematic view of the apparatus for coating photoresist according to the embodiment of the disclosure;

FIG. 2 is a side view of the apparatus for coating photoresist of FIG. 1;

FIG. 3 is a schematic view of the detection device in the apparatus for coating photoresist detecting the substrate; and

FIG. 4 is a schematic diagram of the variation curve of the interval obtained from the computation by the detection device of the apparatus for coating photoresist, whererin the diagraph comprises the variation curve of the interval before the amendment and the variation curve of the interval after amendment.

### DETAILED DESCRIPTION OF THE PREFERRED EMBODIMENTS

The description and explanation are given in more details in the following with reference to the accompanying drawings.

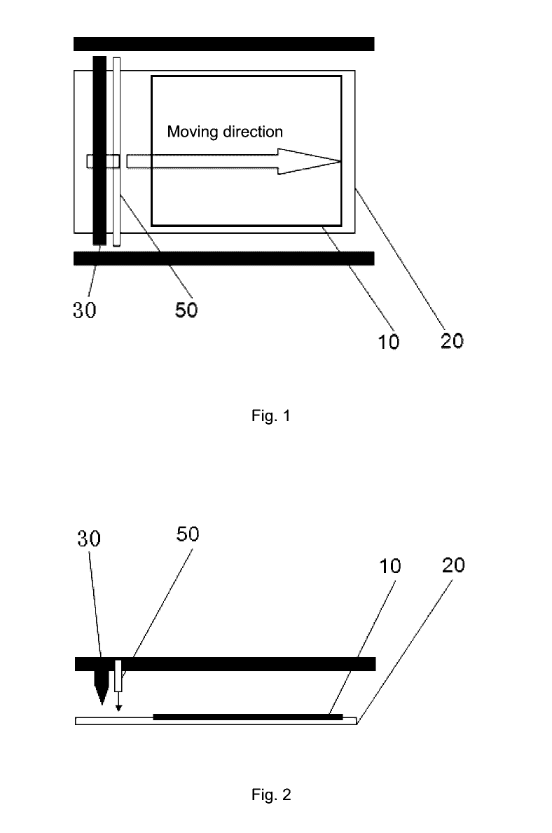

Please refer to FIG. 1 and FIG. 2, the direction of the arrow in FIG. 1 represents the direction of the motion of the nozzle and the detection device. The embodiment of the disclosure provides an apparatus for coating photoresist, which is configured to coat a film on a substrate 10. The apparatus for coating photoresist comprises a workbench 20, a nozzle 30, a nozzle drive (not shown), a detection device 50 and a controller (not shown). The substrate 10 is disposed on the workbench 20. The nozzle drive is configured to drive the movement of the nozzle 30 above the substrate 10 on the workbench 20. The nozzle 30 is disposed across the substrate 10. Specifically, the nozzle 30 is disposed across the whole workbench 20, and the size of the workbench 20 is greater than the size of the substrate 10, so that the workbench 20 is suitable for the substrate 10 with different sizes. The detection device 50 is disposed across the substrate 10, and the detection device 50 is parallel to the nozzle 30. The nozzle 30 is a slit coater. The nozzle 30 is capable of coating a line across the substrate 10 at the same time. The detection device 50 is parallel to the nozzle 30. The detection device 50 is also a line on the substrate 10 to be detected. Thus, the detection of the whole substrate 10 is completed by the detection device 50 moving from one side of the substrate 10 to another side.

In the process of manufacturing the substrate 10, the substrate 10 is stacked by different kinds of films with different patterns, so that the altitude of the surface of the substrate 10 varies. The detection device 50 is configured to detect the variation of the altitude of the surface of the substrate 10 and to compute the variation curve of the interval between the nozzle 30 and the substrate 10. The controller controls the nozzle drive according to the variation curve of the interval between the nozzle and the substrate computed by detection device 50, so that the nozzle drive forces the nozzle 30 moving and adjusts the vertical distance between the nozzle 30 and the substrate 10 according to the variation curve of the interval. The nozzle drive is capable of controlling the movement, the elevating and the lowering of the nozzle 30. When driving the movement of the nozzle 30, the nozzle drive can also adjust the distance between the nozzle 30 and the substrate 10

According to the embodiment of the disclosure, the apparatus for coating photoresist has the design of “The detection device 50 is configured to detect the variation of the altitude of the surface of the substrate 10 and to compute the variation curve of the interval between the nozzle 30 and the substrate 10. The controller controls the nozzle drive according to the variation curve of the interval between the nozzle and the substrate computed by detection device 50, so that the nozzle drive forces the nozzle 30 moving and adjusts the vertical distance between the nozzle 30 and the substrate 10 according to the variation curve of the interval”, so that during the process of coating, the vertical distance between the nozzle 30 and the substrate 10 can be remained consistently, so that the thickness of the coated film is uniform, and the performance of liquid crystal displays is improved.

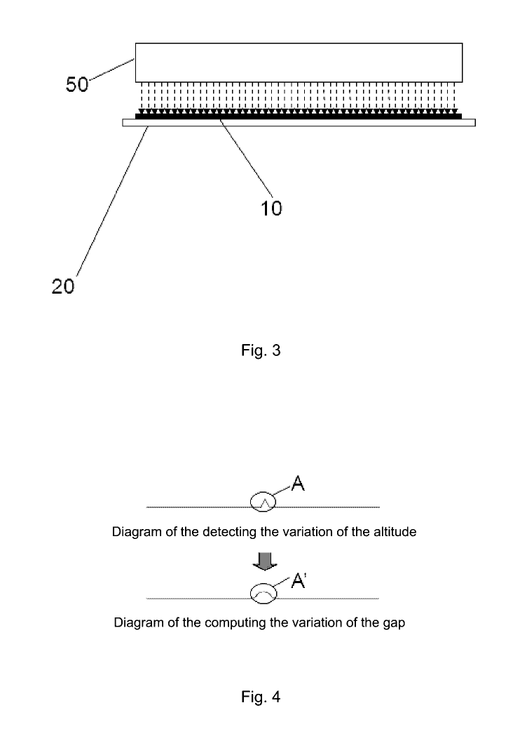

Specifically, the detection device 50 is a reflective laser detector. As shown in FIG. 3, the arrow between the detection device 50 and the substrate 10 represents the light. The detection device 50 comprises an emitter, a receiver and a computing unit. The emitter and the receiver are disposed above the workbench 20. The emitter and the receiver are configured to emit and receive a laser beam. The laser beam passes across the substrate 10. The detection device 50 moves from one side of the workbench 20 to the opposite side so as to accomplish scanning the substrate 10. In some other embodiments, the detection device 50 is a distance detector.

In one embodiment of the disclosure, the controller comprises a mean unit. The mean unit computes an average value of the distance of the interval between the nozzle 30 and each of the point on the substrate 10 according to the variation curve of the interval. The controller emits the average value to the nozzle drive, and the nozzle drive positions the nozzle 30, so that the vertical distance between the nozzle 30 and the substrate 10 is equal to the average value. Specifically, the mean unit obtains a plurality of points in the variation curve of the interval. The points can be chosen randomly. In some other embodiments, the variation curve of the interval is divided into segments evenly, and one or a plurality of points is chosen in each of the section.

Furthermore, the controller further comprises a curve amending unit and a detecting unit. The detecting unit is configured to detect the variation of the variation curve of the interval. When the variation curve having a sudden increase or decrease is detected, the curve amending unit amends the variation curve of the interval, so as to smoothen the position of the sudden increase or decrease, and the controller controls the nozzle drive according to the amended variation curve of the interval. In this embodiment, the detection is focused to the sudden increase or decrease of the altitude of the surface of the substrate 10. For example, the films have a significant difference on the surface of the substrate 10 at the boundary of the films on the substrate 10 because of the stacked films. Thus, the variation curve of the interval varies significantly at the position. In this circumstance, the coating would become abnormal if the nozzle 30 elevates or lowers accompanied by the sudden change of the curve. For instance, the thickness of the coated would become not uniform seriously, and this phenomenon would lead to mura effect. For example, when a position having a higher altitude is detected by the detecting unit, the amending unit sets up the process so that it gradually elevates before the position having a higher altitude, so that the intervals can be shared by a certain range, and it would not change the altitude merely near the point having a higher altitude. Refer to FIG. 4; FIG. 4 includes the diagram of the variation of the detected altitude and the diagram of the variation of the computed gap. Gap represents the interval between the nozzle and the substrate. The diagram of the variation of the detected altitude represents the actual variation of the detected altitude, wherein A represents the position having a sudden change of altitude. The diagram of the variation of the computed gap represents the variation curve of the interval after amendment, wherein A′ represents the variation curve of the interval, of which the curve at position A is amend. The adjustment of the nozzle can be smoother if the nozzle is controlled according to the amend variation curve of the interval, and the coated mass can be assured.

In one embodiment of the disclosure, the controller further comprises an alerting unit. When the difference between the maximum value or the minimum value of the variation curve of the interval and the average value is greater than a predetermined range is detected by the detecting unit, the alerting unit is activated. Practically, the predetermined range is setup according to the products and the materials. The predetermined range can be considered as a safety range, so as to assure the mass of the coating process. When the elevated/lowered distance of the nozzle 30 exceeds the safety range, the alerting unit alerts, so that the staff can adjust the settings manually.

According to another embodiment of the disclosure, the disclosure provides a method for coating photoresist, comprising: detecting the variation of the altitude of the surface of a substrate 10 by a detection device 50; computing the variation curve of the interval between a nozzle 30 and the substrate 10 by a detection device 50; receiving the variation curve of the interval and controlling a nozzle drive by a controller; the nozzle drive forcing the nozzle 30 moving and adjusting the vertical distance between the nozzle 30 and the substrate 10 according to the variation curve of the interval.

According to the method for coating photoresist of the disclosure, the detection device 50 is a reflective laser detector. The detection device 50 comprises an emitter, a receiver and a computing unit. The emitter and the receiver are disposed above the workbench 20. The emitter and the receiver are configured to emit and receive a laser beam. The laser beam passes across the substrate 10. The detection device 50 moves from one side of the workbench 20 to the opposite side so as to accomplish scanning the substrate 10.

Specifically, after the step of receiving the variation curve of the interval by a controller and before the step of controlling a nozzle drive by the controller, the method further comprises: a mean unit in the controller computes an average value of the distance of the interval between the nozzle 30 and each of the point on the substrate 10 according to the variation curve of the interval; the controller emits the average value to the nozzle drive; the nozzle drive poisons the nozzle 30, so that the vertical distance between the nozzle 30 and the substrate 10 is equal to the average value.

After the step of computing an average value of the distance of the interval between the nozzle 30 and each of the point on the substrate 10 by the controller, the method further comprises: detects the variation of the variation curve of the interval by a detecting unit of the controller, when the variation curve having a sudden increase or decrease is detected, a curve amending unit of the controller amends the variation curve of the interval, so as to smoothen the position of the sudden increase or decrease, and the controller controls the nozzle drive according to the amended variation curve of the interval.

When the difference between the maximum value or the minimum value of the and the average value being greater than a predetermined range is detected by the detecting unit, then the alerting unit is activated.

According to the method for coating photoresist of the disclosure, during the process of coating, the vertical distance between the nozzle 30 and the substrate 10 can be remained consistently, so that the thickness of the coated film is uniform, and the performance of liquid crystal displays is improved.

Note that the specifications relating to the above embodiments should be construed as exemplary rather than as limitative of the present disclosure. The equivalent variations and modifications on the structures or the process by reference to the specification and the drawings of the disclosure, or application to the other relevant technology fields directly or indirectly should be construed similarly as falling within the protection scope of the disclosure.

What is claimed is:

1. An apparatus for coating photoresist, configured to coat a film on a substrate, characterized by the apparatus for coating photoresist comprising a workbench, a nozzle, a nozzle drive, a detection device and a controller, wherein the substrate is disposed on the workbench, the nozzle drive is configured to drive the movement of the nozzle above the substrate on the workbench, the nozzle is disposed across the substrate, the detection device is disposed across the substrate, the detection device is parallel to the nozzle, the detection device is configured to detect the variation of the altitude of the surface of the substrate and computes the variation curve of the interval between the nozzle and the substrate, the controller controls the nozzle drive according to the variation curve of the interval between the nozzle and the substrate computed by detection device, so that the nozzle drive forces the nozzle moving and adjusts the vertical distance between the nozzle and the substrate according to the variation curve of the interval.

2. The apparatus for coating photoresist according to claim 1, characterized by the detection device being a reflective laser detector, wherein the detection device comprises an emitter, a receiver and a computing unit, the emitter and the receiver are disposed above the workbench and are configured to emit and receive a laser beam, the laser beam passes across the substrate, and the detection device moves from one side of the workbench to the opposite side so as to accomplish scanning the substrate.

3. The apparatus for coating photoresist according to claim 1, characterized by the controller comprising a mean unit, wherein the mean unit computes an average value of the distance of the interval between the nozzle and each of the point on the substrate according to the variation curve of the interval, the controller emits the average value to the nozzle drive, and the nozzle drive positions the nozzle, so that the vertical distance between the nozzle and the substrate is equal to the average value.

4. The apparatus for coating photoresist according to claim 3, characterized by the controller further comprising a curve amending unit and a detecting unit, wherein the detecting unit is configured to detect the variation of the variation curve of the interval, when the variation curve having a sudden increase or decrease is detected, the curve amending unit amends the variation curve of the interval, so as to smoothen the position of the sudden increase or decrease, and the controller controls the nozzle drive according to the amended variation curve of the interval.

5. The apparatus for coating photoresist according to claim 4, characterized by the controller further comprising an alerting unit, wherein when the difference between the maximum value or the minimum value of the variation curve of the interval and the average value is greater than a predetermined range is detected by the detecting unit, then the alerting unit is activated.

6. A method for coating photoresist, characterized by comprising:
detecting the variation of the altitude of the surface of a substrate by a detection device;
computing the variation curve of the interval between a nozzle and the substrate by a detection device;
receiving the variation curve of the interval and controlling a nozzle drive by a controller; and
the nozzle drive forcing the nozzle moving and adjusting the vertical distance between the nozzle and the substrate according to the variation curve of the interval.

7. The method for coating photoresist according to claim 6, characterized by the detection device being a reflective laser detector, wherein the detection device comprises an emitter, a receiver and a computing unit, the emitter and the receiver are disposed above a workbench and are configured to emit and receive a laser beam, the laser beam passes across the substrate, and the detection device moves from one side of the workbench to the opposite side so as to accomplish scanning the substrate.

8. The method for coating photoresist according to claim 6, characterized by after the step of receiving the variation curve of the interval by a controller and before the step of controlling a nozzle drive by the controller, further comprising: a mean unit in the controller computing an average value of the distance of the interval between the nozzle and each of the point on the substrate according to the variation curve of the interval; the controller emitting the average value to the nozzle drive; the nozzle drive poisoning the nozzle, so that the vertical distance between the nozzle and the substrate being equal to the average value.

9. The method for coating photoresist according to claim 8, characterized by after the step of computing an average value of the distance of the interval between the nozzle and each of the point on the substrate by the controller, further comprising: detecting the variation of the variation curve of the interval by a detecting unit of the controller, when the variation curve having a sudden increase or decrease being detected, a curve amending unit of the controller amending the variation curve of the interval, so as to smoothen the position of the sudden increase or decrease, and the controller controlling the nozzle drive according to the amended variation curve of the interval.

10. The method for coating photoresist according to claim 9, characterized by when the difference between the maximum value or the minimum value of the variation curve of the interval and the average value being greater than a predetermined range being detected by the detecting unit, then an alerting unit being activated.
